(19) United States
(12) Patent Application Publication
(10) Pub. No.: US 2025/0248038 A1
(43) Pub. Date: Jul. 31, 2025

(54) SEMICONDUCTOR MEMORY DEVICE AND ELECTRONIC SYSTEM INCLUDING THE SAME

(71) Applicant: Samsung Electronics Co., Ltd., Suwon-si (KR)

(72) Inventors: Hong Seok CHOI, Suwon-si (KR); Ok Kyu LEE, Suwon-si (KR); Jin Yeol YANG, Suwon-si (KR)

(73) Assignee: Samsung Electronics Co., Ltd., Suwon-si (KR)

(21) Appl. No.: 18/813,787

(22) Filed: Aug. 23, 2024

(30) Foreign Application Priority Data
Jan. 25, 2024 (KR) 10-2024-0011428

(51) Int. Cl. H10B 43/27; H10B 41/27

(52) U.S. Cl. CPC H10B 43/27; H10B 41/27

(57) ABSTRACT

A semiconductor memory device includes a substrate including first and second regions; a first stacked structure on the first region, and having first gate electrode layers and first insulating layers alternately stacked; a second stacked structure on the first stacked structure, and having second gate electrode layers and second insulating layers alternately stacked; an oxide structure on the second region; a first mold structure on the oxide structure, and having nitride and oxide layers alternately stacked; a channel structure penetrating the first and second stacked structures in the first region; and a through structure penetrating the oxide structure and the first mold structure in the second region. The oxide structure and first stacked structure are at a same level, and the first mold structure and second stacked structure are at a same level.

This application claims priority from Korean Patent Application No. 10-2024-0011428 filed on Jan. 25, 2024, in the Korean Intellectual Property Office, and all the benefits accruing therefrom under 35 U.S.C. 119, the contents of which in its entirety are herein incorporated by reference.

### BACKGROUND

The present disclosure relates to semiconductor memory devices and electronic systems including the same. More specifically, the present disclosure relates to semiconductor memory devices including memory cells arranged three-dimensionally and electronic systems including the same.

It is required to increase the degree of integration of semiconductor memory devices to satisfy excellent performance and low price required by consumers. In semiconductor memory devices, because the degree of integration is an important factor in determining the price of a product, an increased degree of integration is particularly required.

In two-dimensional or planar semiconductor memory devices, the degree of integration is mainly determined by an area occupied by unit memory cells, and is therefore greatly affected by the level of fine pattern forming technology. However, since ultra-expensive apparatuses are required to miniaturize the pattern, the degree of integration of two-dimensional semiconductor memory devices is increasing, but is still limited. Accordingly, three-dimensional semiconductor memory devices including memory cells arranged three-dimensionally have been proposed.

### SUMMARY

Some example embodiments of the inventive concepts provide a semiconductor memory device that may improve element performance and reliability.

Some example embodiments of the inventive concepts provide an electronic system including the semiconductor memory device that may improve element performance and reliability.

However, embodiments of the inventive concepts are not restricted to the ones set forth herein. The above and other aspects of the inventive concepts will become more apparent to one of ordinary skill in the art to which the present disclosure pertains by referencing the detailed description of the inventive concepts given below.

Some example embodiments of the inventive concepts provide a semiconductor memory device that includes a substrate including first and second regions, the substrate extending in first and second directions that intersect each other; a first stacked structure stacked on the first region in a third direction perpendicular to the first and second directions, the first stacked structure having first gate electrode layers and first insulating layers alternately stacked; a second stacked structure on the first stacked structure, the second stacked structure having second gate electrode layers and second insulating layers alternately stacked; an oxide structure on the second region; a first mold structure on the oxide structure, the first mold structure having nitride layers and oxide layers alternately stacked; a channel structure extending in the third direction and penetrating the first and second stacked structures in the first region; and a through structure extending in the third direction and penetrating the oxide structure and the first mold structure in the second region. The oxide structure is at a same level as the first stacked structure, and the first mold structure is at a same level as the second stacked structure.

Some example embodiments of the inventive concepts further provide a semiconductor memory device that includes a substrate including a chip region and a scribe region around the chip region, the substrate extending in first and second directions that intersect each other; a first stacked structure stacked on the chip region in a third direction perpendicular to the first and second directions, the first stacked structure having first gate electrode layers stacked thereon; a second stacked structure on the first stacked structure, the second stacked structure having second gate electrode layers stacked thereon; a first mold structure corresponding to the first stacked structure and being on the scribe region, the first mold structure including no nitride; a second mold structure corresponding to the second stacked structure and being on the first mold structure, the second mold structure including nitride; a channel structure extending in the third direction and penetrating the first and second stacked structures in the chip region; and a through structure extending in the third direction and penetrating the first mold structure and the second mold structure in the scribe region.

Some example embodiments of the inventive concepts still further provide an electronic system that includes a main board; a semiconductor memory device on the main board; and a controller electrically connected to the semiconductor memory device, the controller being on the main board. The semiconductor memory device includes a substrate including first and second regions, the substrate extending in first and second directions intersecting each other; a first stacked structure stacked on the first region in a third direction perpendicular to the first and second directions, the first stacked substrate having first gate electrode layers and first insulating layers alternately stacked; a second stacked structure on the first stacked structure, the second stacked structure having second gate electrode layers and second insulating layers alternately stacked; a first mold structure on the second region at a same level as the first stacked structure, the first mold structure including no nitride; a second mold structure on the first mold structure at a same level as the second stacked structure, the second mold structure having nitride layers and oxide layers alternately stacked; a channel structure extending in the third direction and penetrating the first and second stacked structures in the first region; and a through structure extending along the third direction and penetrating the first mold structure and the second mold structure, the through structure defining an air gap therein.

Other example embodiments are included in the detailed description and drawings.

### BRIEF DESCRIPTION OF THE DRAWINGS

The above and other aspects and features of the present disclosure will become more apparent in view of the following description of example embodiments thereof with reference to the attached drawings, in which:

FIG. 1 is a diagram schematically showing a part of a wafer structure used to fabricate a semiconductor memory device according to some example embodiments;

FIG. 2 is a schematic plan view of a semiconductor memory device according to some example embodiments;

FIG. 3 is a cross-sectional view taken along I-I′ of FIG. 2;

FIG. 4 is a cross-sectional view taken along II-II′ of FIG. 2;

FIG. 5 is an enlarged view for explaining a region S of FIG. 3;

FIG. 6 is a schematic plan view of a semiconductor memory device according to some example embodiments;

FIGS. 7 and 8 are diagrams for explaining a semiconductor memory device according to some example embodiments, and are cross-sectional views corresponding to FIGS. 3 and 4, respectively;

FIGS. 9 and 10 are diagrams for explaining a semiconductor memory device according to some example embodiments, and are cross-sectional views corresponding to FIGS. 3 and 4, respectively;

FIGS. 11 and 12 are diagrams for explaining a semiconductor memory device according to some example embodiments, and are cross-sectional views corresponding to FIGS. 3 and 4, respectively;

FIGS. 13 and 14 are diagrams for explaining a semiconductor memory device according to some example embodiments, and are cross-sectional views corresponding to FIGS. 3 and 4, respectively;

FIGS. 15, 16 and 17 are intermediate diagrams for explaining a method for fabricating the semiconductor memory device according to some example embodiments;

FIG. 18 is an example block diagram for explaining an electronic system according to some example embodiments;

FIG. 19 is an exemplary perspective view for explaining an electronic system according to some example embodiments; and

FIG. 20 is a schematic cross-sectional view taken along III-III′ of FIG. 19.

### DETAILED DESCRIPTION

When the terms “about” or “substantially” are used in this specification in connection with a numerical value, it is intended that the associated numerical value includes a manufacturing or operational tolerance (e.g., ±10%) around the stated numerical value. Moreover, when the words “generally” and “substantially” are used in connection with geometric shapes, it is intended that precision of the geometric shape is not required but that latitude for the shape is within the scope of the disclosure. Further, regardless of whether numerical values or shapes are modified as “about” or “substantially,” it will be understood that these values and shapes should be construed as including a manufacturing or operational tolerance (e.g., ±10%) around the stated numerical values or shapes. When ranges are specified, the range includes all values therebetween such as increments of 0.1%.

Also, for example, “at least one of A, B, and C” and similar language (e.g., “at least one selected from the group consisting of A, B, and C”) may be construed as A only, B only, C only, or any combination of two or more of A, B, and C, such as, for instance, ABC, AB, BC, and AC.

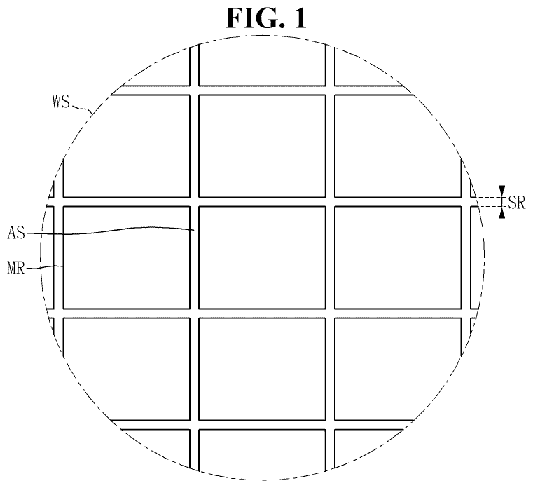

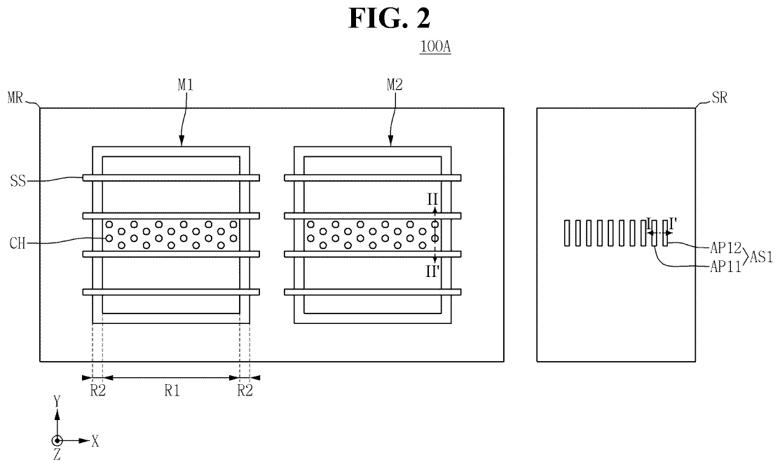

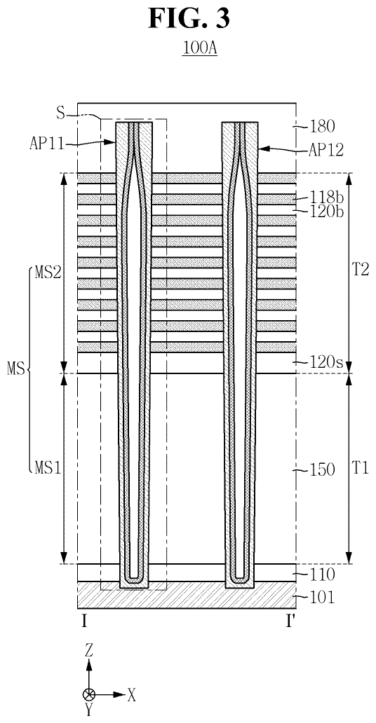

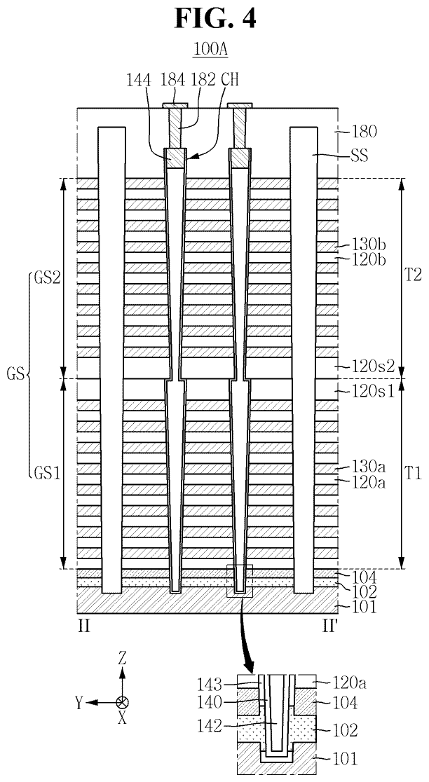

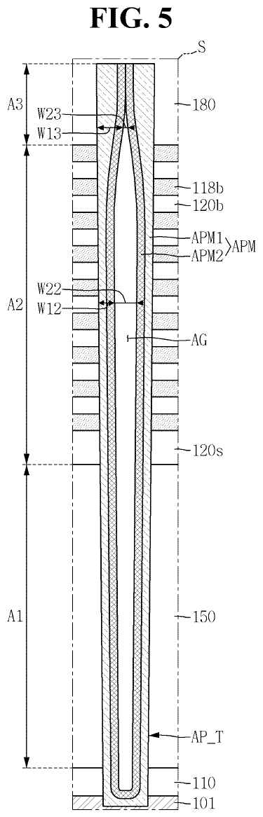

FIG. 1 is a diagram schematically showing a part of a wafer structure used to fabricate a semiconductor memory device according to some example embodiments. FIG. 2 is a schematic plan view of a semiconductor memory device according to some example embodiments. FIG. 3 is a cross-sectional view taken along I-I′ of FIG. 2. FIG. 4 is a cross-sectional view taken along II-II′ of FIG. 2. FIG. 5 is an enlarged view for explaining a region S of FIG. 3.

Referring to FIGS. 1 and 2, a wafer structure WS for fabricating a semiconductor memory device may include a plurality of main regions MR and a plurality of scribe lane regions SR. The plurality of main regions MR may be spaced apart from each other by the plurality of scribe lane regions SR.

The plurality of scribe lane regions SR may be regions for cutting the wafer structure WS in a sawing process to separate each of the plurality of main regions MR after the fabricating process on the plurality of main regions MR is completed. Each of the plurality of main regions MR may mean a chip region in which a “semiconductor chip” or a “die” is disposed. For example, each of the plurality of main regions MR may have a rectangular shape in a plane, but the shape of the main region MR is not limited thereto.

The wafer structure WS may include a semiconductor chip formed in the main region MR, and a through structure AS formed in the scribe lane region SR. The through structure AS may include a first through structure AS1 to be described below.

Referring to FIG. 2, a semiconductor memory device 100A may include a plurality of memory structures M1 and M2, and a first through structure AS1 disposed around the plurality of memory structures M1 and M2.

In some example embodiments, the first through structure AS1 may be disposed adjacent to a corner of the main region MR, but the specific position at which the first through structure AS1 is disposed is not limited thereto.

In some example embodiments, the semiconductor memory device 100A may include two memory structures M1 and M2, but the number of memory structures M1 and M2 is not limited thereto and may be greater than two.

Each of the plurality of memory structures M1 and M2 may include separation structures SS, a first region R1 disposed between the separation structures SS, and a second region R2 disposed on at least one side of the first region R1. The first region R1 may be a memory cell array region or a memory cell region. The second region R2 may be a stair region.

Referring to FIGS. 2 to 4, the semiconductor memory device 100A according to some example embodiments may include a substrate 101, a first stacked structure GS1, a second stacked structure GS2, a channel structure CH, a first mold structure MS1, a second mold structure MS2, and a first through structure AS1.

The substrate 101 may have an upper face extending in a first direction X and a second direction Y that intersect each other. The substrate 101 may include a semiconductor material, for example, a group IV semiconductor, a group III-V compound semiconductor or a group II-VI compound semiconductor. For example, the group IV semiconductor may include silicon, germanium or silicon-germanium. The substrate 101 may be provided as a bulk wafer, an epitaxial layer, an SOI (Silicon On Insulator) layer, an SeOI (Semiconductor On Insulator) layer, or the like.

First and second horizontal conductive layers 102 and 104 may be sequentially stacked and disposed on an upper face of the substrate 101. The second horizontal conductive layer 104 may cover the first horizontal conductive layer 102.

The first horizontal conductive layer 102 may function as at least a part of a common source line of the semiconductor memory device 100A, and may function, for example, as a common source line together with the substrate 101. As shown in the enlarged view of FIG. 4, the first horizontal conductive layer 102 may be directly connected to the channel layer 140 around the channel layer 140.

The first and second horizontal conductive layers 102 and 104 may include a semiconductor material, and may include, for example, polycrystalline silicon. In this case, at least the first horizontal conductive layer 102 may be a layer doped with impurities of the same conductivity type as the substrate 101, and the second horizontal conductive layer 104 may be a doped layer or a layer containing impurities diffused from the conductive layer 102. However, the material of the second horizontal conductive layer 104 is not limited to a semiconductor material.

The first through structure AS1 may at least partially penetrate the horizontal insulating layer 110 disposed on the upper face of the substrate 101. The horizontal insulating layer 110 may include an insulating material, for example, silicon oxide, silicon nitride, silicon carbide or silicon oxynitride.

The semiconductor memory device 100A according to some example embodiments may include a stacked structure GS on a substrate 101. The stacked structure GS may include a first stacked structure GS1 on the substrate 101 and a second stacked structure GS2 on the first stacked structure GS1.

The first stacked structure GS1 may include first gate electrode layers 130a and first interlayer insulating layers 120a that are alternately stacked on the main region MR in a third direction Z perpendicular to the first and second directions X and Y. The second stacked structure GS2 may include second gate electrode layers 130b and second interlayer insulating layers 120b that are alternately stacked on each other in the third direction Z.

The gate electrode layers 130a and 130b may include a lower gate electrode that forms a gate of a ground selection transistor, memory gate electrodes that form a plurality of memory cells, and an upper gate electrode that forms gates of string selection transistors. The number of memory gate electrodes that form the memory cells may be determined depending on the capacity of the semiconductor memory device 100A. According to the some example embodiments, the upper and lower gate electrodes may each be one or more, and may have a structure that is identical to or different from that of the memory gate electrode.

In some example embodiments, the gate electrode layers 130a and 130b may further include a gate electrode that is disposed above the upper gate electrode and/or below the lower gate electrode, and forms an erasure transistor used for an erasure operation using a gate induced leakage current (GIDL) phenomenon. Furthermore, in some gate electrode layers 130a and 130b, for example, the memory gate electrodes adjacent to the upper or lower gate electrodes may be dummy gate electrodes.

The gate electrode layers 130a and 130b are stacked on the first region (R1 of FIG. 2) to be spaced apart in the third direction Z, and extend from the first region (R1 of FIG. 2) to the second region (R2 of FIG. 2) at different lengths to form a stepped structure. The gate electrode layers 130a and 130b may form a stepped structure between the gate electrode layers 130a and 130b along the first and second directions X and Y. In some example embodiments, in at least some of the gate electrode layer 130a and 130b, a certain number, for example, two to six gate electrode layers 130a and 130b form a single gate group, and may form a stepped structure between the gate groups along the first and second directions X and Y.

For example, the gate electrode layers 130a and 130b may include a metal material, for example, but not limited to, tungsten (W). According to some example embodiments, the gate electrode layers 130a and 130b may include polycrystalline silicon or metal silicide materials. In some example embodiments, the gate electrode layers 130a and 130b may further include a diffusion barrier. For example, the diffusion barrier may include, but not limited to, tungsten nitride (WN), tantalum nitride (TaN), titanium nitride (TiN) or combinations thereof.

The interlayer insulating layers 120a and 120b may be disposed between the gate electrode layers 130a and 130b or between sacrificial insulating layers 118b to be described below. Some of the interlayer insulating layers 120a and 120b may be alternately stacked with the gate electrode layers 130a and 130b to form first and second stacked structures GS1 and GS2. Others of the interlayer insulating layers 120a and 120b may be alternately stacked with the sacrificial insulating layers 118b to form the second mold structure MS2. For example, the interlayer insulating layers 120a and 120b may include insulating materials for example, but not limited to, silicon oxide or silicon nitride.

The semiconductor memory device 100A according to some example embodiments may include a mold structure MS on the substrate 101. The mold structure MS may include a first mold structure MS1 on the substrate 101, and a second mold structure MS2 on the first mold structure MS1.

The first mold structure MS1 may be disposed on the scribe lane region SR. The first mold structure MS1 may include an oxide 150. For example, the first mold structure MS1 may include, but not limited to, only the oxide 150 without nitride. When the first mold structure MS1 includes only the oxide 150, the first mold structure MS1 may be referred to as an oxide structure.

The second mold structure MS2 may include first sacrificial insulating layers 118b and second interlayer insulating layers 120b that are alternately stacked on the first mold structure MS1 in the third direction Z. The stacked first sacrificial insulating layers 118b may be spaced apart from the second gate electrode layers 130b in the horizontal direction, and be disposed in parallel with the second gate electrode layers 130b. The first sacrificial insulating layers 118b may be layers that remain after some of the fabricating processes of the semiconductor memory device 100A and are replaced with the gate electrode layers 130a and 130b.

The first sacrificial insulating layers 118b may include a material different from the second interlayer insulating layer 120b. For example, the first sacrificial insulating layers 118b may include silicon nitride, and the second interlayer insulating layers 120b may include silicon oxide, and the first sacrificial insulating layers 118b may be called a nitride layer, and the second interlayer insulating layers 120b may be called an oxide layer.

The second mold structure MS2 may further include a connection insulating layer 120s disposed on the first mold structure MS1. The connection insulating layer 120s may include an insulating material, for example, at least one of silicon oxide, silicon nitride, and silicon oxynitride. The connection insulating layer 120s may include, but not limited to, the same material as the interlayer insulating layers 120a and 120b.

The first stacked structure GS1 may further include a first connection insulating layer 120s1 disposed on the uppermost gate electrode layer 130a among the first gate electrode layers 130a. The second stacked structure GS2 may further include a second connection insulating layer 120s2 disposed below the lowermost gate electrode layer 130b among the second gate electrode layers 130b.

The first and second connection insulating layers 120s1 and 120s2 may include an insulating material, for example, at least one of silicon oxide, silicon nitride, and silicon oxynitride. The first and second connection insulating layers 120s1 and 120s2 may include, but not limited thereto, the same material as the interlayer insulating layers 120a and 120b.

Referring to FIGS. 3 and 4 together, the first mold structure MS1 may be located at the same level as the first stacked structure GS1, and the second mold structure MS2 may be located at the same level as the second stacked structure GS2.

For example, on the basis of the third direction Z, a thickness T1 of the first mold structure MS1 is the same as a thickness T1 of the first stacked structure GS1, and a thickness T2 of the second mold structure MS2 may be the same as a thickness T2 of the second stacked structure GS2.

For example, on the basis of the third direction Z, the first mold structure MS1 may correspond to the thickness T1 of the first stacked structure GS1, and the second mold structure MS2 may correspond to the second stacked structure GS2.

The channel structures CH may be disposed in the first region (R1 of FIG. 2) in each of the plurality of memory structures M1 and M2.

Each of the channel structures CH may include a lower channel structure penetrating the first stacked structure GS1, and an upper channel structure penetrating the second stacked structure GS2. The upper channel structure may be disposed on the lower channel structure and be connected to the lower channel structure. That is, the lower channel structure and the upper channel structure may have a connected form. The upper face of the lower channel structure and the lower face of the upper channel structure may be located at the same level as the upper face of the first stacked structure GS1. The upper face of the lower channel structure may be located at substantially the same level as the upper face of the first connection insulating layer 120s1.

In this way, the expression “substantially the same level” may be understood to include a case where even though they are formed together through the same process, there is actually a slight difference in level due to process error or the like.

The channel structures CH each form one memory cell string, and may be spaced apart from each other on the substrate 101, while forming rows and columns. The channel structures CH may be disposed in a lattice form from viewpoint of a plan view, or may be disposed in a zigzag form in one direction. The channel structures CH have a hole-like columnar shape, and may have an inclined side face that becomes narrower toward the substrate 101 depending on the aspect ratio.

Each of the lower channel structure and the upper channel structure may have sloped side faces that become narrower toward the substrate 101. In some example embodiments, the width of the uppermost part of the lower channel structure may be greater than the width of the lowermost part of the upper channel structure. Therefore, the channel structures CH may include a curved portion that is formed as the width changes at the level of the region in which the lower channel structure and the upper channel structure are connected.

As shown in the enlarged view of FIG. 4, each of the channel structures CH may further include a gate dielectric layer 143, a channel buried insulating layer 142 between the channel layers 140, and an upper channel pad 144, in addition to the channel layer 140.

The channel layer 140 may be formed in an annular shape that surrounds a channel embedded insulating layer 142 therein, but may have a columnar shape such as a cylinder or a prism without the channel embedded insulating layer 142 according to some example embodiments. The channel layer 140 may be connected to the first horizontal conductive layer 102 at the bottom. The channel layer 140 may include a semiconductor material such as polycrystalline silicon or single crystal silicon, and the semiconductor material may be an undoped material or a material containing p-type or n-type impurities.

A gate dielectric layer 143 may be disposed between the gate electrode layers 130 (e.g., 130a and 130b) and the channel layer 140. Although it is not specifically shown, the gate dielectric layer 143 may include a tunneling layer, a charge storage layer, and a blocking layer that are sequentially stacked from the channel layer 140. The tunneling layer may tunnel the charge to the charge storage layer, and may include, for example, silicon oxide (SiO₂), silicon nitride (Si₃N₄), silicon oxynitride (SiON) or combinations thereof. The charge storage layer may be a charge trap layer or a floating gate conductive layer. The blocking layer may include silicon oxide (SiO₂), silicon nitride (Si₃N₄), silicon oxynitride (SiON), high-k dielectric materials, or combinations thereof. In some example embodiments, at least a part of the gate dielectric layer 143 may extend horizontally along the gate electrode layers 130a and 130b.

A channel pad 144 may be disposed above the channel layer 140 in each of the channel structures CH. The channel pad 144 may be disposed to cover the upper face of the channel embedded insulating layer 142 and to be electrically connected to the channel layer 140. The channel pad 144 may include, for example, doped polycrystalline silicon.

The separation structures SS penetrate the gate electrode layers 130a and 130b, the interlayer insulating layers 120a and 120b, the connection insulating layers 120s1 and 120s2, and the horizontal conductive layers 102 and 104, extend in the third direction Z, and may be connected to the substrate 101. Each of the separation structures SS may be located inside a trench extending along the first direction X from viewpoint of a plan view.

The separation structures SS may be spaced apart from each other in the second direction Y. That is, the separation structures SS may separate the gate electrode layers 130a and 130b from each other along the second direction Y. The separation structures SS may have a shape in which the width decreases toward the substrate 101 due to a high aspect ratio. In some example embodiments, the separation structures SS may include an insulating material formed inside the trench.

The semiconductor memory device 100A may further include upper contact structures 182 and upper wirings 184. The upper contact structures 182 may penetrate the upper insulating layer 180, and be connected to the channel structures CH. The upper contact structures 182 may include a conductive material, and may include, for example, but not limited to, tungsten (W), copper (Cu), aluminum (Al), and the like.

The upper wirings 184 may form an upper wiring structure electrically connected to the channel structures CH and the gate electrodes 130a and 130b. The upper wirings 184 may include a conductive material, and may include, but not limited to, tungsten (W), copper (Cu), aluminum (Al) or the like. In some example embodiments, the upper contact structures 182 and the upper wirings 184 may include the same material, but are not limited thereto.

The first through structure AS1 may extend in the third direction Z to penetrate the first mold structure MS1 and the second mold structure MS2, in the scribe lane region SR.

The first through structure AS1 may include, but not limited to, first through patterns AP11 and AP12 spaced apart from each other in the first direction X. The number of first through patterns AP11 and AP12 is not limited to that shown.

Referring to FIG. 5, the first through patterns AP11 and AP12 may each be formed inside the trenches AP_T penetrating the first mold structure MS1 and the second mold structure MS2. The first through patterns AP11 and AP12 may include an air gap AG formed therein, and a conductive material layer APM extending along an inner wall of the trench AP_T. For example, the first mold structure MS1 comprising the oxide 150, and the second mold structure MS2, may define a trench AP_T penetrating the first mold structure MS1 and the second mold structure MS2. The first through structure AS1 including the first through patterns AP11 and AP12 includes the conductive material APM extending along an inner wall of the trench AP_T. For example, the first through patterns AP11 and AP12 may further define air gaps AG therein.

The conductive material layer APM may include a first conductive layer APM1 extending along a side wall and a bottom face of the trench AP_T, and a second conductive layer APM2 on the first conductive layer APM1.

Each of the first and second conductive layers APM1 and APM2 may include, but not limited to, at least one of tungsten (W), aluminum (Al), and copper (Cu).

Each of the first through patterns AP11 and AP12 may include a first region A1 adjacent to the first mold structure MS1, a second region A2 adjacent to the second mold structure MS2, and a third region A3 adjacent to the upper insulating layer 180.

A width W13 in the third region A3 of the conductive material layer APM may be greater than a width W12 in the second region A2. That is, the width of the conductive material layer APM may be maximum in a region that is farthest away from the substrate 101 in the third direction Z. For example, the widths of each of the first and second conductive layers APM1 and APM2 may be maximum in a region adjacent to the upper insulating layer 180, for example, in an upper region of the second mold structure MS2.

A width W23 in the third region A3 of the air gap AG may be smaller than a width W22 of the second region A2. The width of the air gap AG may be smallest in a region that is farthest away from the substrate 101 in the third direction Z. That is, the width of the air gap AG may be minimum in the region adjacent to the upper insulating layer 180, for example, in the upper region of the second mold structure MS2.

A process of separating a plurality of main regions (MR of FIGS. 1 and 2) from the wafer structure (WS of FIG. 1) may be performed by a wafer dicing process. The wafer dicing process may be performed by a process of cutting a part of the scribe lane region (SR of FIGS. 1 and 2) using a laser. For example, a stealth dicing process may be used to separate the semiconductor chips. An initial crack may be generated inside the substrate (101 of FIG. 3) by irradiating a portion of the substrate (101 of FIG. 3) corresponding to the scribe lane region (SR of FIGS. 1 and 2) with a laser. The semiconductor chips may be separated, by growing or propagating the generated crack.

According to some example embodiments, by forming the through structure AS1 in the scribe lane region SR, cracks generated to separate the semiconductor chips may be guided to move straight. Accordingly, in a semiconductor memory device in which two or more mold structures having different physical properties are stacked, the performance and reliability of the above-mentioned cutting process can be improved.

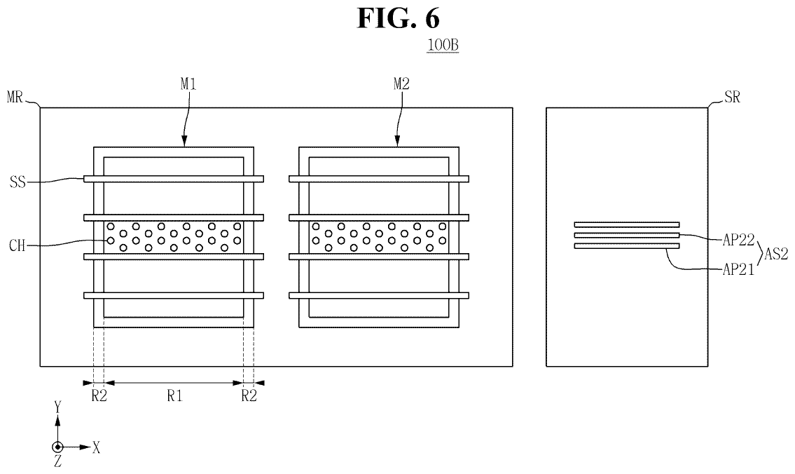

FIG. 6 is a schematic plan view of a semiconductor memory device according to some example embodiments. For convenience, the explanation will focus on the differences from the contents explained using FIGS. 1 to 5.

Referring to FIG. 6, a semiconductor memory device 100B may include a plurality of memory structures M1 and M2, and a second through structure AS2 disposed around the plurality of memory structures M1 and M2. The through structure (AS of FIG. 1) may include a second through structure AS2.

The second through structure AS2 may include, but not limited to, second through patterns AP21 and AP22 spaced apart from each other in the second direction Y. Meanwhile, the number of second through patterns AP21 and AP22 is not limited to the shown example.

The explanation about the first through structure AS1 explained using FIGS. 1 to 5 may be similarly applied to the second through structure AS2, except for the aforementioned differences. For example, in FIG. 2 the first through patterns AP11 and AP12 are spaced apart from each other in the first direction X and extend along the second direction Y, and in FIG. 6 the second through patterns AP21 and AP22 are spaced apart from each other in the second direction Y and extend along the first direction X.

Furthermore, the explanation about the main region MR explained using FIGS. 1 to 5 may also be similarly applied to the main region MR in FIG. 6.

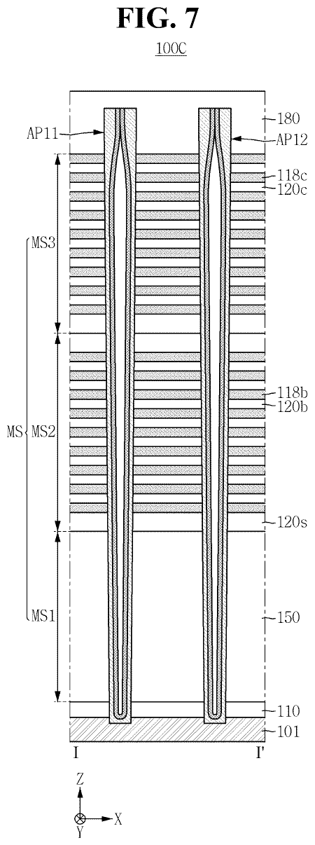

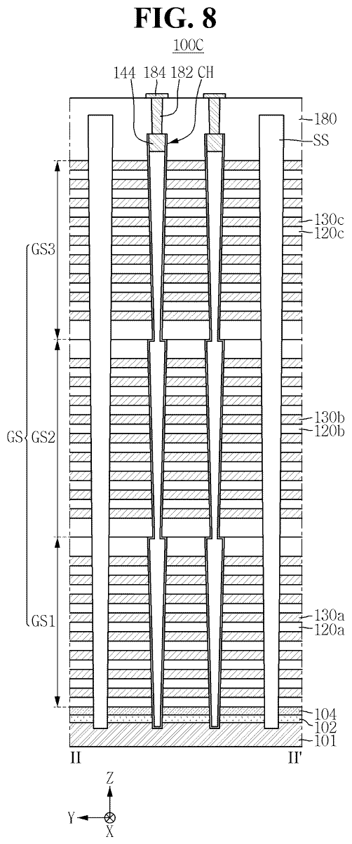

FIGS. 7 and 8 are diagrams for explaining a semiconductor memory device according to some example embodiments, and correspond to FIGS. 3 and 4, respectively. For convenience, the explanation will focus on the differences from the contents explained using FIGS. 1 to 6.

Referring to FIGS. 7 and 8, a semiconductor memory device 100C may have a structure of the first through structure AS1 and the plurality of memory structures M1 and M2 different from that shown in FIG. 3.

The stacked structure GS may include a first lower stacked structure GS1, a first intermediate stacked structure GS2, and a first upper stacked structure GS3. That is, unlike FIG. 3, the semiconductor memory device 100C may have a three-stage stacked structure instead of a two-stage stacked structure. However, the number of stacked structures is not limited thereto, and may be stacked to have a structure of three or more stages depending on the embodiment.

The mold structure MS may include a first lower mold structure MS1, a first intermediate mold structure MS2, and a first upper mold structure MS3. The first lower mold structure MS1 and the first intermediate mold structure MS2 may have the same structure as the first mold structure MS1 and the second mold structure MS2 described in FIG. 3, and the first upper mold structure MS3 may be stacked on the first intermediate mold structure MS2 in a shape similar to the stacked structure of the first intermediate mold structure MS2.

The first intermediate stacked structure GS2 may be disposed between the first lower stacked structure GS1 and the first upper stacked structure GS3. The first intermediate mold structure MS2 may be disposed between an oxide structure MS1 and the first upper mold structure MS3.

That is, the first lower mold structure MS1 may include only oxide, and each of the first intermediate mold structure MS2 and the first upper mold structure MS3 may have a stacked structure of an oxide layer and a nitride layer.

Accordingly, even in the semiconductor memory device in which three or more mold structures are stacked, the performance and reliability of the cutting process may be improved as described above.

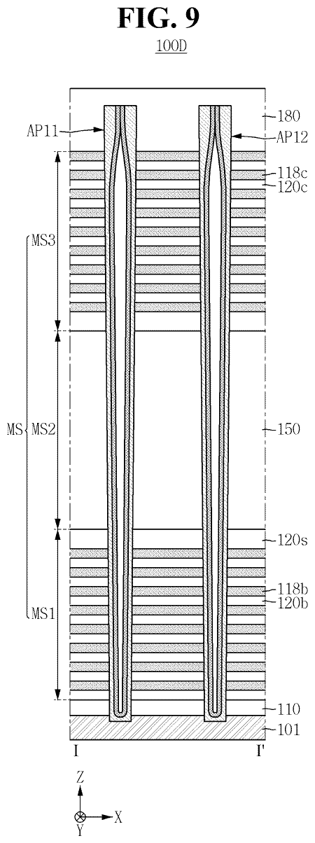

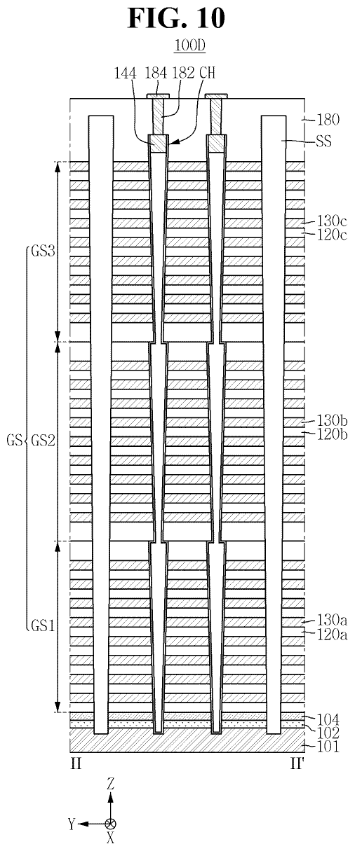

FIGS. 9 and 10 are diagrams for explaining a semiconductor memory device according to some example embodiments, and correspond to FIGS. 3 and 4, respectively. For convenience, the explanation will focus on the differences from the contents explained using FIGS. 1 to 8.

Referring to FIGS. 9 and 10, a semiconductor memory device 100D may have a structure of a mold structure MS different from that shown in FIGS. 7 and 8.

The mold structure MS may include a second lower mold structure MS1, a second intermediate mold structure MS2, and a second upper mold structure MS3. The second intermediate mold structure MS2 and the second upper mold structure MS3 may have the same structure as the first mold structure MS1 and the second mold structure MS2 described in FIG. 3, and the second lower mold structure MS1 may be stacked on the substrate 101 in the shape similar to the stacked structure of the second upper mold structure MS3.

The second lower mold structure MS1 may be disposed between the oxide structure MS2 and the substrate 101.

That is, the second intermediate mold structure MS2 may include only oxide, and each of the second lower mold structure MS1 and the second upper mold structure MS3 may have a stacked structure of an oxide layer and a nitride layer.

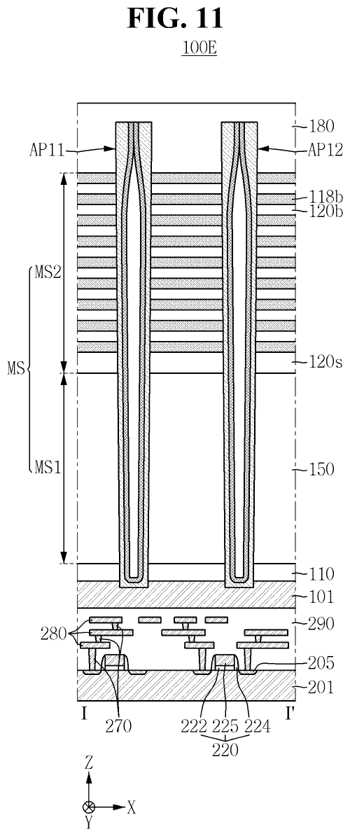

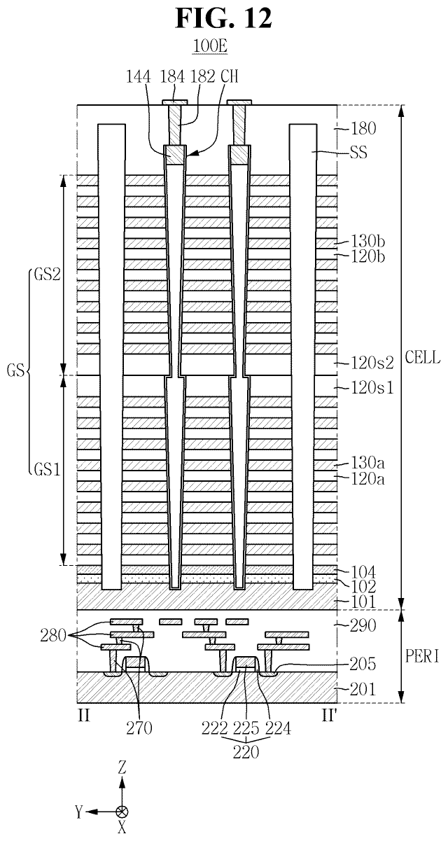

FIGS. 11 and 12 are diagrams for explaining a semiconductor memory device according to some example embodiments, and correspond to FIGS. 3 and 4, respectively. For convenience, the explanation will focus on the differences from the contents explained using FIGS. 1 to 10.

Referring to FIGS. 11 and 12, a semiconductor memory device 100E may include a memory cell region CELL and a peripheral circuit region PERI stacked vertically.

The memory cell region CELL may be disposed above the peripheral circuit region PERI, but is not limited thereto. In some example embodiments, the memory cell region CELL may be disposed below the peripheral circuit region PERI.

As in FIG. 4, the memory cell region CELL may include a substrate 101, first and second horizontal conductive layers 102 and 104, a stacked structure GS, connection insulating layers 120s1 and 120s2, a channel structure CH, a separation structure SS, an upper insulating layer 180, upper contact structures 182, and upper wirings 184.

The peripheral circuit region PERI may include a base substrate 201, circuit elements 220 disposed on the base substrate 201, circuit contact plugs 270, and circuit wiring lines 280.

The base substrate 201 may have an upper face extending in the first and second directions X and Y. Separate element separation layers may be formed on the base substrate 201 to define an active region. Source/drain regions 205 containing impurities may be disposed in a part of the active region. The base substrate 201 may include a semiconductor material, for example, a group IV semiconductor, a group III-V compound semiconductor or a group II-VI compound semiconductor. The base substrate 201 may be provided as a bulk wafer or an epitaxial layer. In some example embodiments, the upper substrate 101 may be provided as a polycrystalline semiconductor layer, such as a polycrystalline silicon layer, or an epitaxial layer.

Circuit elements 220 may include a horizontal transistor. Each circuit element 220 may include a circuit gate dielectric layer 222, a spacer layer 224, and a circuit gate electrode 225. Source/drain regions 205 may be disposed inside the base substrate 201 on either side of the circuit gate electrode 225. The circuit elements 220 may be electrically connected to the gate electrode layers 130a and 130b and/or the channel structures CH.

A peripheral region insulating layer 290 may be disposed over the circuit elements 220 on the base substrate 201. The circuit contact plugs 270 may penetrate the peripheral region insulating layer 290, and be connected to the source/drain region 205. Electrical signals may be applied to the circuit elements 220 by the circuit contact plugs 270. In a region that is not shown, the circuit contact plugs 270 may also be connected to the circuit gate electrode 225. The circuit wiring lines 280 may be connected to the circuit contact plugs 270 and may be disposed in multiple layers.

In the semiconductor memory device 100E, the peripheral circuit region PERI is first fabricated, and then the substrate 101 of the memory cell region CELL may be formed thereon to fabricate the memory cell region CELL. The substrate 101 may have the same size as the base substrate 201 or may be formed to be smaller than the base substrate 201. Although not specifically shown, the memory cell region CELL and the peripheral circuit region PERI may be connected to each other. For example, in a region that is not shown, one ends of the gate electrode layers 130a and 130b in the second direction Y may be electrically connected to the circuit elements 220.

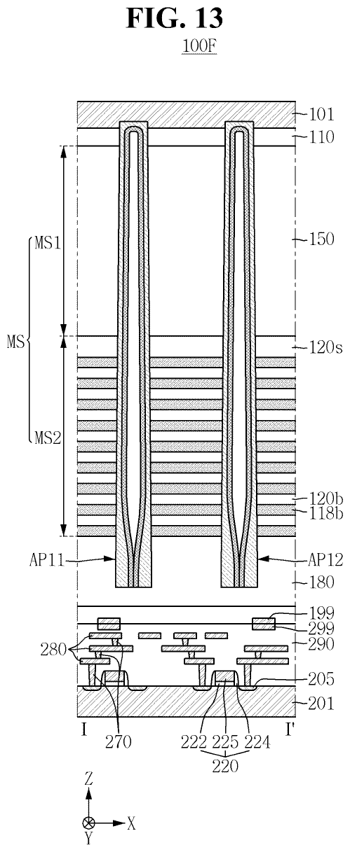

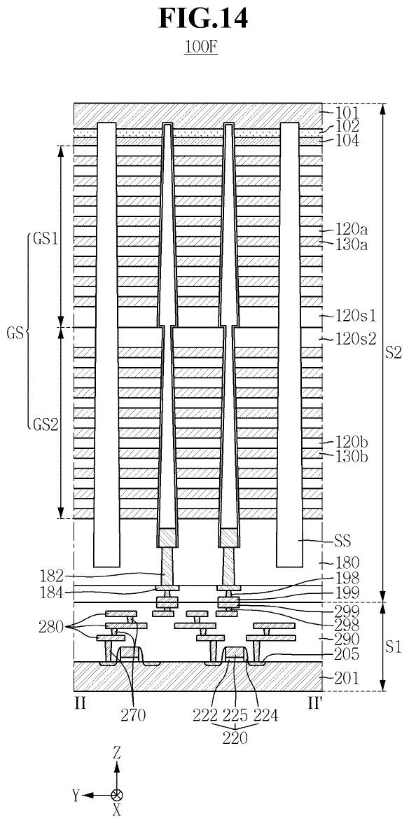

FIGS. 13 and 14 are diagrams for explaining a semiconductor memory device according to some example embodiments, and correspond to FIGS. 3 and 4, respectively. For convenience, the explanation will focus on the differences from the contents explained using FIGS. 1 to 12.

Referring to FIGS. 13 and 14, a semiconductor memory device 100F may include a first structure S1 and a second structure S2 that are bonded in a wafer bonding manner.

The explanation of the peripheral circuit region PERI described above referring to FIGS. 11 and 12 may be applied to the first structure S1. However, the first structure S1 may further include first bonding vias 298 and first bonding pads 299, which are bonding structures.

The first bonding vias 298 are disposed above the uppermost circuit wiring lines 280 and may be connected to the circuit wiring lines 280. The first bonding pads 299 may be at least partially connected to the first bonding vias 298 on the first bonding vias 298. The first bonding pads 299 may be connected to the second bonding pads 199 of the second structure S2. The first bonding pads 299 and the second bonding pads 199 may provide an electrical connection path according to the bonding between the first structure S1 and the second structure S2. The first bonding vias 298 and the first bonding pads 299 may include a conductive material, for example, copper (Cu).

Similarly as in FIG. 4, the second structure S2 may include a substrate 101, first and second horizontal conductive layers 102 and 104, a stacked structure GS, connection insulating layers 120s1 and 120s2, a channel structure CH, a separation structure SS, an upper insulating layer 180, upper contact structures 182, and upper wirings 184. The second structure S2 may further include second bonding vias 198 and second bonding pads 199, which are bonding structures. Although not specifically shown, the second structure S2 may further include a protective layer that covers the upper face of the substrate 101.

The second bonding vias 198 and the second bonding pads 199 may be disposed below the lowest wiring lines. The second bonding vias 198 may be connected to the wiring lines and the second bonding pads 199, and the second bonding pads 199 may be joined with the first bonding pads 299 of the first structure S1. The second bonding vias 198 and the second bonding pads 199 may include a conductive material, for example, copper (Cu).

The first structure S1 and the second structure S2 may be bonded by copper (Cu)-copper (Cu) bonding using the first bonding pads 299 and the second bonding pads 199. The aforementioned copper (Cu)-copper (Cu) bonding, the first structure S1 and the second structure S2 may also be joined by dielectric-dielectric bonding. The dielectric-dielectric bonding may be a junction by dielectric layers that form a part of each of the peripheral region insulating layer 290 and the upper insulating layer 180 and surround each of the first bonding pads 299 and the second bonding pads 199. Accordingly, the first structure S1 and the second structure S2 may be joined without separate adhesive layers.

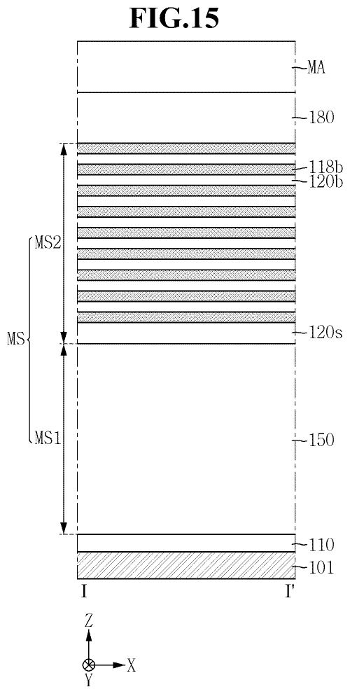

FIGS. 15 to 17 are intermediate diagrams for explaining a method for fabricating a semiconductor memory device according to some example embodiments. For convenience, the explanation will focus on the differences from the contents explained using FIGS. 1 to 5. For reference, FIGS. 15 to 17 are diagrams for explaining a process in which the through structure (AS1 of FIG. 2) is formed on the scribe lane region (SR of FIGS. 1 and 2) of the substrate 101.

Referring to FIG. 15, a horizontal insulating layer 110, a first mold structure MS1, a connection insulating layer 120s, a second mold structure MS2, an upper insulating layer 180 and a mask layer MA may be formed sequentially on the scribe lane region (SR of FIGS. 1 and 2) of the substrate 101.

The first mold structure MS1 may include an oxide 150, and the second mold structure MS2 may have a structure in which nitride layers 118b and oxide layers 120b are alternately stacked.

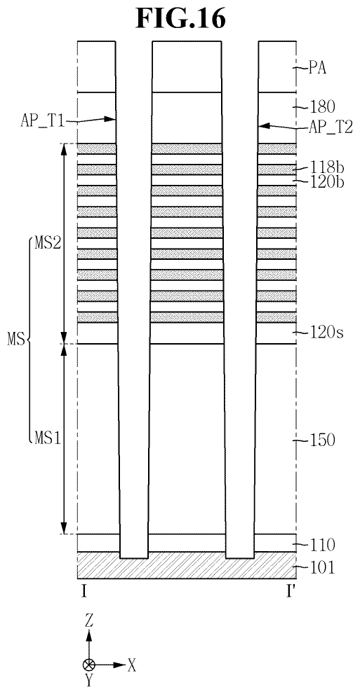

Referring to FIG. 16, each of the first and second trenches AP_T1 and AP_T2 which penetrate at least a part of the horizontal insulating layer 110, the first mold structure MS1, the connection insulating layer 120s, the second mold structure MS2, the upper insulating layer 180, and the mask layer MA may be formed. The mask layer MA may be patterned by the first and second trenches AP_T1 and AP_T2 to form a plurality of mask patterns PA.

Although not specifically shown, the first and second trenches AP_T1 and AP_T2 may be formed by transferring a pattern onto the mask layer MA, performing an exposure process on the corresponding mask layer MA region, and then performing a dry etching process to correspond to the exposed region. Although sputtering, chemical vapor etching, reactive ion etching, and the like may be used as the etching process, the etching process is not limited thereto.

After that, the plurality of mask patterns PA may be removed.

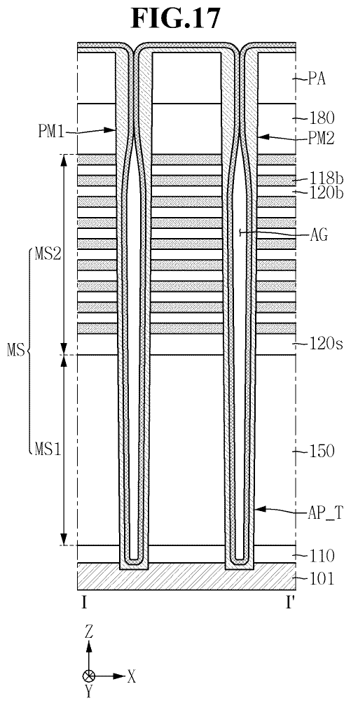

Referring to FIG. 17, first and second pre-conductive material layers PM1 and PM2 may be formed in the first and second trenches AP_T1 and AP_T2, respectively.

The first and second pre-conductive material layers PM1 and PM2 may include, but not limited to, for example, tungsten (W).

A physical vapor deposition process may be used to gap-fill the interior of the first and second trenches AP_T1 and AP_T2. A relatively large amount of the first and second pre-conductive material layers PM1 and PM2 may be deposited on the upper portions of the first and second trenches AP_T1 and AP_T2, due to the overhang phenomenon.

In some example embodiments, the process of removing the relatively large amount of first and second pre-conductive material layers PM1 and PM2 deposited due to the above-mentioned overhang may be skipped at least partially. As a result, the upper portions of the first and second trenches AP_T1 and AP_T2 are blocked by the first and second pre-conductive material layers PM1 and PM2, and an air gap AG as an empty space may be formed inside the first and second trenches AP_T1 and AP_T2.

Accordingly, the semiconductor memory device 100A described using FIGS. 3 and 4 may be formed.

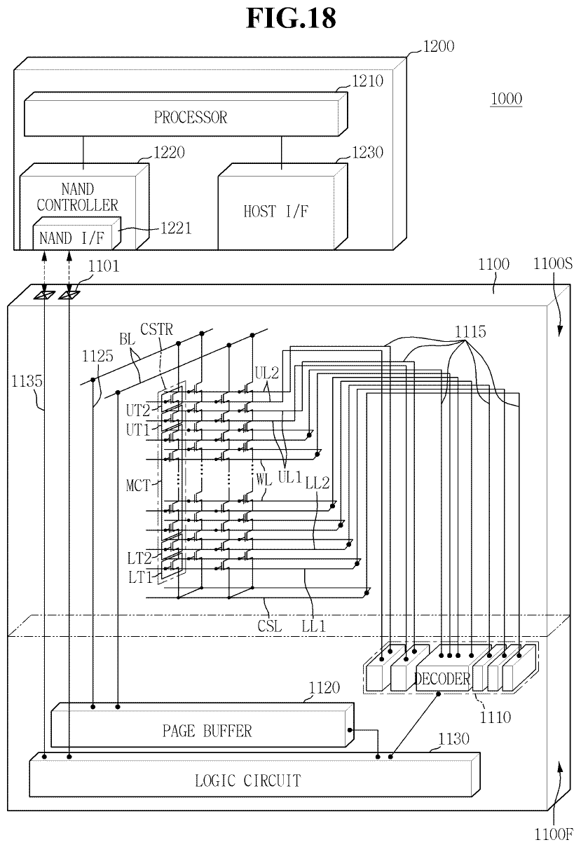

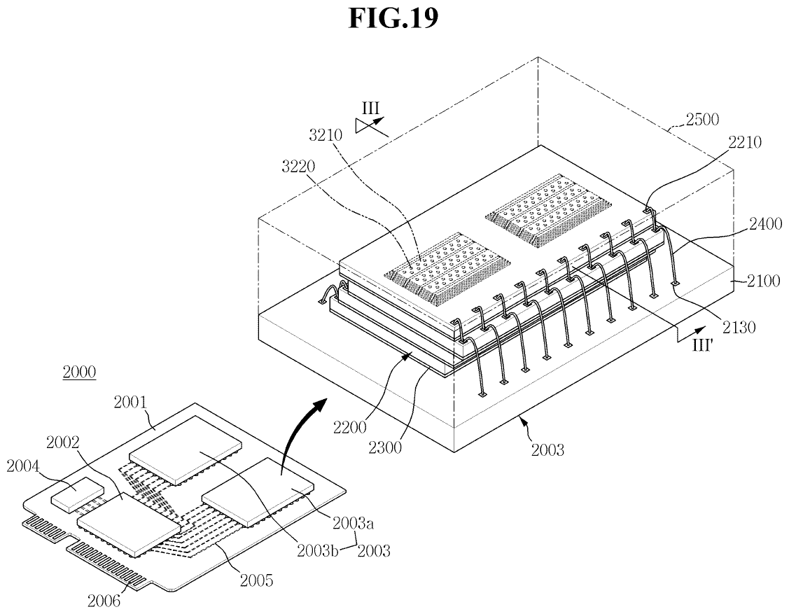

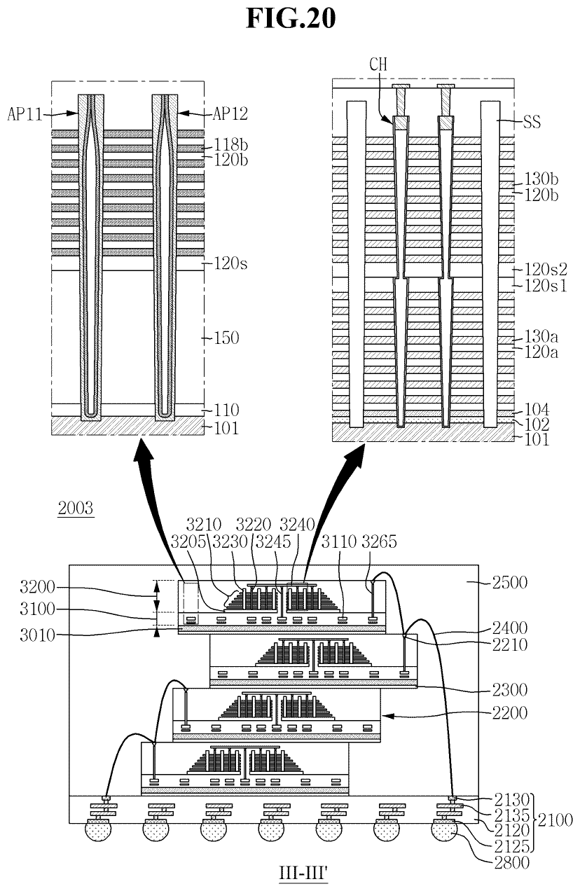

FIG. 18 is an example block diagram for explaining an electronic system according to some example embodiments. FIG. 19 is a perspective view for explaining the electronic system according to some example embodiments. FIG. 20 is a schematic cross-sectional view taken along III-III′ of FIG. 19.

Referring to FIG. 18, an electronic system 1000 may include a semiconductor memory device 1100, and a controller 1200 that is electrically connected to the semiconductor memory device 1100. The electronic system 1000 may be a storage device that includes one or multiple semiconductor memory devices 1100, or an electronic device that includes the storage device. For example, the electronic system 1000 may be an SSD device (solid state drive device), a USB (Universal Serial Bus), a computing system, a medical device or a communication device that includes one or multiple semiconductor memory devices 1100.

The semiconductor memory device 1100 may be a non-volatile memory device and may be, for example, a NAND flash memory device explained above referring to FIGS. 1 to 14. The semiconductor memory device 1100 may include a first semiconductor structure 1100F, and a second semiconductor structure 1100S on the first semiconductor structure 1100F. In some example embodiments, the first semiconductor structure 1100F may be disposed next to the second semiconductor structure 1100S. The first semiconductor structure 1100F may be a peripheral circuit structure including a decoder circuit 1110, a page buffer 1120, and a logic circuit 1130. The second semiconductor structure 1100S may be a memory cell structure that includes a bit line BL, a common source line CSL, word lines WL, first and second gate upper lines UL1 and UL2, first and second gate lower lines LL1 and LL2, and memory cell strings CSTR between the bit line BL and the common source line CSL.

In the second semiconductor structure 1100S, each memory cell string CSTR may include lower transistors LT1 and LT2 adjacent to the common source line CSL, upper transistors UT1 and UT2 adjacent to the bit line BL, and a plurality of memory cell transistors MCT disposed between the lower transistors LT1 and LT2 and the upper transistors UT1 and UT2. The number of lower transistors LT1 and LT2 and the number of upper transistors UT1 and UT2 may be modified variously depending on some example embodiments.

In some example embodiments, the upper transistors UT1 and UT2 may include a string selection transistor, and the lower transistors LT1 and LT2 may include a ground selection transistor. The gate lower lines LL1 and LL2 may be gate electrodes of the lower transistors LT1 and LT2, respectively. The word lines WL may be gate electrode layers of the memory cell transistors MCT, and the gate upper lines UL1 and UL2 may be gate electrodes of the upper transistors UT1 and UT2, respectively.

In some example embodiments, the lower transistors LT1 and LT2 may include a lower erasure control transistor LT1 and a ground selection transistor LT2 that are connected in series. The upper transistors UT1 and UT2 may include a string selection transistor UT1 and an upper erasure control transistor UT2 that are connected in series. At least one of the lower erasure control transistor LT1 and the upper erasure control transistor UT1 may be used for an erasure operation of erasing the data stored in the memory cell transistor MCT, using the GIDL phenomenon.

The common source line CSL, the first and second gate lower lines LL1 and LL2, the word lines WL, and the first and second gate upper lines UL1 and UL2 may be electrically connected to the decoder circuit 1110 through first connection wirings 1115 extending from inside of the first structure 1100F to the second structure 1100S. The bit lines BL may be electrically connected to the page buffer 1120 through second connection wirings 1125 extending from inside of the first structure 1100F to the second structure 1100S.

In the first structure 1100F, the decoder circuit 1110 and the page buffer 1120 may perform a control operation on at least one selected memory cell transistor among the plurality of memory cell transistors MCT. The decoder circuit 1110 and the page buffer 1120 may be controlled by the logic circuit 1130. The semiconductor device 1000 may communicate with the controller 1200 through an I/O pad 1101 electrically connected to the logic circuit 1130. The I/O pad 1101 may be electrically connected to the logic circuit 1130 through the I/O connection wiring 1135 extending from inside of first structure 1100F to the second structure 1100S.

The controller 1200 may include a processor 1210, a NAND controller 1220, and a host interface 1230. According to some example embodiments, the electronic system 1000 may include a plurality of semiconductor memory devices 1100, and the controller 1200 may control the plurality of semiconductor memory devices 1100.

The processor 1210 may control the operation of the overall electronic system 1000, including the controller 1200. The processor 1210 may operate according to a predetermined firmware, and may control the NAND controller 1220 to access the semiconductor memory device 1100. The NAND controller 1220 may include a NAND interface 1221 that processes communication with the semiconductor memory device 1100. Control command for controlling the semiconductor memory device 1100, data to be recorded in the memory cell transistors MCT of the semiconductor memory device 1100, data to be read from the memory cell transistors MCT of the semiconductor memory device 1100, and the like may be transmitted through the NAND interface 1221. The host interface 1230 may provide a communication function between the electronic system 1000 and an external host. When receiving the control command from the external host through the host interface 1230, the processor 1210 may control the semiconductor memory device 1100 in response to the control command.

Referring to FIG. 19, the electronic system 2000 according to the some example embodiments of the present disclosure may include a main board 2001, a controller 2002 mounted on the main board 2001, one or more semiconductor packages 2003, and a DRAM 2004. The semiconductor package 2003 and the DRAM 2004 may be connected to the controller 2002 by wiring patterns 2005 formed on the main board 2001.

The main board 2001 may include a connector 2006 including a plurality of pins coupled to an external host. In the connector 2006, the number and placement of the plurality of pins may vary depending on the communication interface between the electronic system 2000 and the external host. In some example embodiments, the electronic system 2000 may communicate with the external host according to any one of interfaces such as M-Phy for USB (Universal Serial Bus), PCI-Express (Peripheral Component Interconnect Express), SATA (Serial Advanced Technology Attachment), and UFS (Universal Flash Storage). In some example embodiments, the electronic system 2000 may operate by power supplied from the external host through the connector 2006. The electronic system 2000 may further include a PMIC (Power Management Integrated Circuit) that distributes the power supplied from the external host to the controller 2002 and the semiconductor package 2003.

The controller 2002 may record data in the semiconductor package 2003 or read data from the semiconductor package 2003, and may improve the operating speed of the electronic system 2000.

The DRAM 2004 may be a buffer memory for relieving a speed difference between the semiconductor package 2003, which is a data storage space, and the external host. The DRAM 2004 included in the electronic system 2000 may also operate as a kind of cache memory, and may also provide a space for temporarily storing data in the control operation on the semiconductor package 2003. When the DRAM 2004 is included in the electronic system 2000, the controller 2002 may further include a DRAM controller for controlling the DRAM 2004, in addition to a NAND controller for controlling the semiconductor package 2003.

The semiconductor package 2003 may include first semiconductor packages 2003a and second semiconductor packages 2003b that are spaced apart from each other. Each of the first semiconductor packages 2003a and the second semiconductor packages 2003b may be a semiconductor package that includes a plurality of semiconductor chips 2200. Each of the first semiconductor packages 2003a and the second semiconductor packages 2003b may include a package substrate 2100, semiconductor chips 2200 on the package substrate 2100, adhesive layers 2300 placed on the lower faces of each of the package chips 220, a connecting structure 2400 for electrically connecting the semiconductor chips 2200 and the package substrate 2100, and a molding layer 2500 that covers the semiconductor chips 2200 and the connecting structure 2400 on the package substrate 2100.

The package substrate 2100 may be a printed circuit board that includes package upper pads 2130. Each semiconductor chip 2200 may include an I/O pad 2210. The I/O pad 2210 may correspond to the I/O pad 1101 of FIG. 18. Each of the semiconductor chips 2200 may include gate stacked structures 3210 and channel structures 3220. Each of the semiconductor chips 2200 may include the semiconductor memory device explained above with reference to FIGS. 1 to 14.

In some example embodiments, the connecting structure 2400 may be a bonding wire that electrically connects the I/O pad 2210 and the package upper pads 2130. Therefore, in each of the first semiconductor packages 2003a and the second semiconductor packages 2003b, the semiconductor chips 2200 may be electrically connected to each other in a bonding wire manner, and may be electrically connected to the package upper pads 2130 of the package substrate 2100. According to some example embodiments, in each of the first semiconductor packages 2003a and the second semiconductor packages 2003b, the semiconductor chips 2200 may be electrically connected to each other by a connecting structure including a through electrode (Through Silicon Via, TSV) instead of the connecting structure 2400 of the bonding wire manner.

In some example embodiments, the controller 2002 and the semiconductor chips 2200 may also be included in a single package. In some example embodiments, the controller 2002 and the semiconductor chips 2200 are mounted on a separate interposer substrate different from the main board 2001, and the controller 2002 and the semiconductor chips 2200 may also be connected to each other by the wiring formed on the interposer substrate.

Referring to FIG. 20, in the semiconductor package 2003, the package substrate 2100 may be a printed circuit board. The package substrate 2100 may include a package substrate body portion 2120, package upper pads 2130 (see FIG. 19) placed on an upper face of the package substrate body portion 2120, lower pads 2125 placed on a lower face of the package substrate body portion 2120 or exposed through the lower face, and inner wirings 2135 that electrically connect the upper pads 2130 and the lower pads 2125 inside the package substrate body portion 2120. The upper pads 2130 may be electrically connected to the connecting structure 2400. The lower pads 2125 may be connected to the wiring patterns 2005 of the main board 2001 of the electronic system 2000 through conductive connections 2800, as in FIG. 19.

Each of the semiconductor chips 2200 may include a semiconductor substrate 3010, and a first semiconductor structure 3100 and a second semiconductor structure 3200 sequentially stacked on the semiconductor substrate 3010. The first semiconductor structure 3100 may include a peripheral circuit region including the peripheral wirings 3110. The second semiconductor structure 3200 may include a common source line 3205, a gate stacked structure 3210 on the common source line 3205, channel structures 3220 and separation regions 3230 that penetrate the gate stacked structure 3210, bit lines 3240 electrically connected to the memory channel structures 3220, and contact plugs electrically connected to the word lines WL (see FIG. 18) of the gate stacked structure 3210.

Each of the semiconductor chips 2200 may include first and second stacked structures GS1 and GS2, and a channel structure CS and a separation structure SS that extend to penetrate the and the first and second stacked structures GS1 and GS2, as described above with reference to FIGS. 1 to 5.

Furthermore, each of the semiconductor chips 2200 may include first and second mold structures MS1 and MS2, and a through structure AS that extends to penetrate them, as described above with reference to FIGS. 1 to 5. For example, the first mold structure MS1 may be an oxide structure 150, and the second mold structure MS2 may be a structure in which an oxide layer 120b and a nitride layer 118b are stacked. The through structure AS may include a plurality of through patterns AP11 and AP12 that intersect each other and are spaced apart from each other in the horizontal direction.

An air gap may be formed inside each of the plurality of through patterns AP11 and AP12. The plurality of through patterns AP11 and AP12 may include a conductive material layer that extends along the inner walls of the trench penetrating the first and second mold structures MS1 and MS2.

Each of the semiconductor chips 2200 may include a through wiring 3245 that is electrically connected to the peripheral wirings 3110 of the first semiconductor structure 3100 and extends into the second semiconductor structure 3200. The through wiring 3245 may be disposed outside the gate stacked structure 3210, and may be further disposed to penetrate the gate stacked structure 3210. Each of the semiconductor chips 2200 may further include an I/O connection wiring 3265 that is electrically connected to the I/P pad 2210.

Each of the semiconductor chips 2200 may further include an I/P pad 2210 (see FIG. 18) that is electrically connected to the peripheral wirings 3110 of the first semiconductor structure 3100.

One or more of the elements disclosed above may include or be implemented in processing circuitry such as hardware including logic circuits; a hardware/software combination such as a processor executing software; or a combination thereof. For example, the processing circuitry more specifically may include, but is not limited to, a central processing unit (CPU), an arithmetic logic unit (ALU), a digital signal processor, a microcomputer, a field programmable gate array (FPGA), a System-on-Chip (SoC), a programmable logic unit, a microprocessor, an application-specific integrated circuit (ASIC), etc.

Although some example embodiments of the present disclosure have been described above with reference to the accompanying drawings, the present disclosure is not limited to the some example embodiments, and may be fabricated in various different forms. Those skilled in the art will appreciate that the present disclosure may be embodied in other specific forms without changing the technical spirit or essential features of the present disclosure. Accordingly, the above-described embodiments should be understood in all respects as illustrative and not restrictive.

What is claimed is:

1. A semiconductor memory device comprising:
a substrate including first and second regions, the substrate extending in first and second directions that intersect each other;
a first stacked structure stacked on the first region in a third direction perpendicular to the first and second directions, the first stacked structure having first gate electrode layers and first insulating layers alternately stacked;
a second stacked structure on the first stacked structure, the second stacked structure having second gate electrode layers and second insulating layers alternately stacked;
an oxide structure on the second region;
a first mold structure on the oxide structure, the first mold structure having nitride layers and oxide layers alternately stacked;
a channel structure extending in the third direction and penetrating the first and second stacked structures in the first region; and
a through structure extending in the third direction and penetrating the oxide structure and the first mold structure in the second region,
wherein the oxide structure is at a same level as the first stacked structure, and
the first mold structure is at a same level as the second stacked structure.

2. The semiconductor memory device of claim 1,
wherein the through structure includes first through patterns spaced apart from each other in the first direction.

3. The semiconductor memory device of claim 1,
wherein the through structure includes first through patterns spaced apart from each other in the second direction.

4. The semiconductor memory device of claim 1,
wherein the oxide structure and the first mold structure define a trench penetrating the oxide structure and the first mold structure, the through structure including a conductive material layer extending along an inner wall of the trench.

5. The semiconductor memory device of claim 4,
wherein a width of the conductive material layer is maximum in a region of the first mold structure farthest away from the substrate in the third direction.

6. The semiconductor memory device of claim 4,
wherein the conductive material layer includes tungsten.

7. The semiconductor memory device of claim 1,
wherein the through structure defines an air gap therein.

8. The semiconductor memory device of claim 7,
wherein a width of the air gap is smallest in a region of the first mold structure farthest away from the substrate in the third direction.

9. The semiconductor memory device of claim 1, further comprising:
a third stacked structure between the first stacked structure and the second stacked structure, the third stacked structure having third gate electrode layers and third insulating layers alternately stacked; and
a second mold structure between the oxide structure and the first mold structure, the second mold structure having nitride layers and oxide layers alternately stacked.

10. The semiconductor memory device of claim 1, further comprising:
a third stacked structure between the first stacked structure and the substrate, the third stacked structure having third gate electrode layers and third insulating layers alternately stacked; and
a second mold structure between the oxide structure and the substrate, the second mold structure having nitride layers and oxide layers alternately stacked.

11. The semiconductor memory device of claim 1,
wherein the oxide structure does not include nitride.

12. A semiconductor memory device comprising:
a substrate including a chip region and a scribe region around the chip region, the substrate extending in first and second directions that intersect each other;
a first stacked structure stacked on the chip region in a third direction perpendicular to the first and second directions, the first stacked structure having first gate electrode layers stacked on each other;
a second stacked structure on the first stacked structure, the second stacked structure having second gate electrode layers stacked on each other;
a first mold structure corresponding to the first stacked structure and being on the scribe region, the first mold structure including no nitride;
a second mold structure corresponding to the second stacked structure and being on the first mold structure, the second mold structure including nitride;
a channel structure extending in the third direction and penetrating the first and second stacked structures in the chip region; and
a through structure extending in the third direction and penetrating the first mold structure and the second mold structure in the scribe region.

13. The semiconductor memory device of claim 12,
wherein the through structure includes:
first through patterns spaced apart from each other in the second direction; and
second through patterns spaced apart from each other in the first direction.

14. The semiconductor memory device of claim 12,
wherein the first mold structure is located at a same level as the first stacked structure along the third direction, and
the second mold structure is located at a same level as the second stacked structure along the third direction.

15. The semiconductor memory device of claim 12,
wherein the through structure defines an air gap therein, and
a width of the air gap is minimum in an upper region of the second mold structure.

16. The semiconductor memory device of claim 12,
wherein the first mold structure and the second mold structure define a trench penetrating the first mold structure and the second mold structure, and
the through structure includes a first conductive layer extending along an inner wall of the trench, and a second conductive layer on the first conductive layer.

17. The semiconductor memory device of claim 16,
wherein widths of the first and second conductive layers are maximum in an upper region of the second mold structure.

18. The semiconductor memory device of claim 16,
wherein the first and second conductive layers include at least one of tungsten, aluminum, and copper.

19. An electronic system comprising:
a main board;
a semiconductor memory device on the main board; and
a controller electrically connected to the semiconductor memory device, the controller being on the main board,
wherein the semiconductor memory device includes
a substrate including first and second regions, the substrate extending in first and second directions intersecting each other,
a first stacked structure stacked on the first region in a third direction perpendicular to the first and second directions, the first stacked structure having first gate electrode layers and first insulating layers alternately stacked,
a second stacked structure on the first stacked structure, the second stacked structure having second gate electrode layers and second insulating layers alternately stacked,
a first mold structure on the second region at a same level as the first stacked structure, the first mold structure including no nitride,
a second mold structure on the first mold structure at a same level as the second stacked structure, the second mold structure having nitride layers and oxide layers alternately stacked,
a channel structure extending in the third direction and penetrating the first and second stacked structures in the first region, and
a through structure extending in the third direction and penetrating the first mold structure and the second mold structure in the second region, the through structure defining an air gap therein.

20. The electronic system of claim 19,
wherein the first mold structure and the second mold structure define a trench penetrating the first mold structure and the second mold structure, and
the through structure includes a conductive material layer extending along an inner wall of the trench.
